(19) United States
(12) Patent Application Publication
(10) Pub. No.: US 2021/0160414 A1
(43) Pub. Date: May 27, 2021

(54) DISPLAY HAVING OPTICAL SENSOR AND OPTICAL SENSING MODULE THEREOF

(71) Applicant: Egis Technology Inc., Taipei City (TW)

(72) Inventors: TONG-LONG FU, Taipei City (TW); CHEN-CHIH FAN, Taipei City (TW); WEI JUNG WANG, Taipei City (TW)

(21) Appl. No.: 17/014,101

(22) Filed: Sep. 8, 2020

Related U.S. Application Data
(60) Provisional application No. 62/940,454, filed on Nov. 26, 2019.

(30) Foreign Application Priority Data
Aug. 12, 2020 (CN) 202010807302.5

(51) Int. Cl. H04N 5/235; H04N 5/225; G09G 3/3208; G06K 9/00

(52) U.S. Cl. CPC H04N 5/235; H04N 5/2256; G09G 2320/0247; G06K 9/00013; G09G 3/3208

(57) ABSTRACT

A display includes: a display panel having display pixels and providing visible light to display information; an optical sensor sensing an object disposed above the display panel; and an infrared (IR) source providing initial IR light penetrating through the display panel to illuminate the object, which generates to-be-sensed IR light penetrating through the display panel and received by the optical sensor, which obtains an image signal, wherein the IR source is disabled in a first period when the display pixels are enabled, and is enabled in a second period of a disable period when the display pixels are disabled. The second period lags behind the first period by a third period. An optical sensing module is also provided.

### CROSS-REFERENCE TO RELATED APPLICATIONS

This application claims priorities of U.S. Provisional Patent Application Ser. No. 62/940,454, filed on Nov. 26, 2019 and China Patent Application Ser. No. 202010807302.5, filed on Aug. 12, 2020, the entire contents of which are hereby incorporated by reference.

### BACKGROUND OF THE INVENTION

### Field of the Invention

This disclosure relates to a display having an optical sensor and an optical sensing module thereof, and more particularly to a display having an optical sensor and an optical module of the display, wherein different clocks respectively drive the optical sensor and the display to prevent a white flickering phenomenon of the display.

### Description of the Related Art

Today's mobile electronic devices (e.g., mobile phones, tablet computers, notebook computers and the like) are usually equipped with user biometrics recognition systems including different techniques regarding to, for example, fingerprint, face, iris and the like to protect security of personal data. Portable devices applied to mobile phones, smart watches or the like also have the mobile payment function, which further becomes a standard function for the user's biometrics recognition. The portable device, such as the mobile phone or the like, is further developed toward the full-display (or super-narrow border) trend, so that conventional capacitive fingerprint buttons can no longer be used, and a new minimized optical imaging device (very similar to the conventional camera module having complementary metal-oxide semiconductor (CMOS) image sensor (referred to as CIS) sensing members and an optical lens module) is thus evolved. The minimized optical imaging device is disposed under the display as an under-display device. The image of the object (more particularly the fingerprint) placed above the display can be captured through the partial light-permeable display (more particularly the organic light emitting diode (OLED) display), and this can be called as fingerprint on display (FOD).

FOD needs to overcome many problems. First, the sensing light needs to penetrate through the display panel at least one time, so that the light can be received by the optical imaging device and the fingerprint image can be obtained. Second, the displaying light of the display panel and the sensing light cannot mutually interfere with each other to prevent the displaying and sensing results from being affected. Furthermore, the manufacturer needs to design the fingerprint sensor to work in conjunction with the well-grown driving method of the current display panel to solve the above-mentioned problems. Thus, the FOD technology still needs to be further improved.

### BRIEF SUMMARY OF THE INVENTION

Therefore, an object of this disclosure is to provide a display having an optical sensor and an optical module thereof, wherein different clocks respectively drive the optical sensor and the display to prevent a white flickering phenomenon of the display while achieving an optical sensing function.

To achieve the above-identified object, a display is provided. The display includes: a display panel having display pixels and providing visible light to display information; an optical sensor being disposed below the display panel and sensing an image of an object disposed above the display panel; and an infrared (IR) source being disposed below the display panel and providing initial IR light penetrating through the display panel to illuminate the object, which generates to-be-sensed IR light penetrating through the display panel and being received by the optical sensor, which obtains an image signal representing the image, wherein the IR source is disabled in a first period when the display pixels are enabled, and is enabled in a second period of a disable period when the display pixels are disabled, and the second period lags behind the first period by a third period.

This disclosure also provides an optical sensing module including: an optical sensor sensing an image of an object through a display panel placed above the optical sensor, wherein a first driver drives display pixels of the display panel to display information; an IR source being disposed below the display panel and providing initial IR light penetrating through the display panel to illuminate the object, which generates to-be-sensed IR light penetrating through the display panel and being received by the optical sensor, which obtains an image signal representing the image; and a second driver to be connected to first driver, wherein the second driver generates a second clock signal according to a first clock signal, according to which the first driver drives the display pixels, to drive the IR source to generate the initial IR light, so that the second clock signal disables the IR source in a first period when the first clock signal enables the display pixels; and that the second clock signal enables the IR source in a second period of a disable period when the first clock signal disables the display pixels, wherein the second period lags behind the first period by a third period.

With the above-mentioned embodiments, different clocks can be used to respectively drive the optical sensor and the display to prevent a white flickering phenomenon of the display while achieving the optical sensing function. For the display provided with the FOD sensor, the first clock signal for driving the display pixels can be obtained through the device driver interface of the existing OLED display panel to define the second clock signal for driving the IR source, wherein the second clock signal and the first clock signal have the corresponding delay times to avoid the white flickering phenomenon.

Further scope of the applicability of this disclosure will become apparent from the detailed description given hereinafter. However, it should be understood that the detailed description and specific examples, while indicating preferred embodiments of this disclosure, are given by way of illustration only, since various changes and modifications within the spirit and scope of this disclosure will become apparent to those skilled in the art from this detailed description.

### BRIEF DESCRIPTION OF THE SEVERAL VIEWS OF THE DRAWINGS

FIG. 1 is a schematic view showing a display and an optical sensing module thereof according to a preferred embodiment of this disclosure.

FIGS. 2A and 2B are timing charts showing two examples of clock signals for the display.

FIGS. 3A to 3C are partial schematic views showing three examples of the optical sensing modules.

FIG. 4 is a partial schematic view showing a light-absorbing material disposed above an IR source.

### DETAILED DESCRIPTION OF THE INVENTION

In this disclosure, it is found that when display pixels of the OLED panel are lighted up with a frame rate generally ranging from 60 to 120 Hz, light rays with some wavelengths (e.g., 940 nm) illuminate the display pixels to cause the white flickering phenomenon in partial regions.

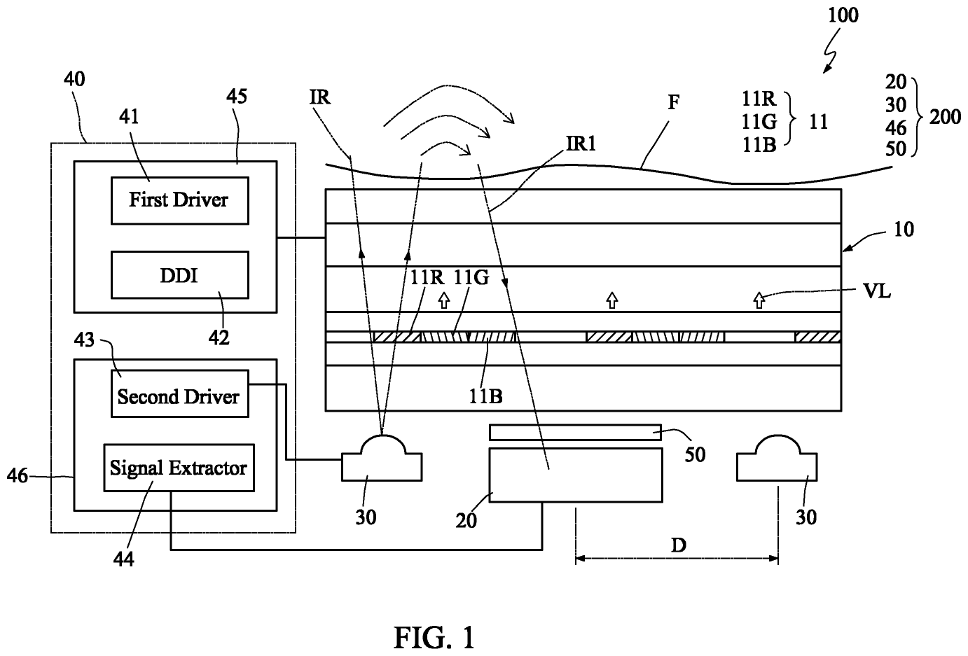

Referring to FIG. 1, this embodiment provides a display 100 including a display panel 10, an optical sensor 20, an IR source 30 and a controller 40.

The display panel 10 has display pixels 11, and provides upward visible light VL to display information. The display pixels 11 include a red pixel 11R, a green pixel 11G and a blue pixel 11B. In this example, the self-luminous display panel, such as the OLED panel, is explained, but this disclosure is not limited to thereto. This embodiment is also applicable to any display panel having the displayed information affected by the IR source 30.

The optical sensor 20 is disposed below or under the display panel 10, and senses an image of an object F disposed above the display panel 10. In this example, the optical sensor 20 to be explained is a fingerprint sensor for sensing a fingerprint image of a finger. In other examples, the optical sensor 20 may be other biometrics characteristic sensors for sensing biometrics characteristics, such as vein patterns, blood oxygen concentrations, iris, face and the like.

The IR source 30 is disposed below or under the display panel 10, and provides initial infrared light IR penetrating through the display panel 10 to illuminate the object F. The object F generates to-be-sensed infrared light IR1 penetrating through the display panel 10 and being received by the optical sensor 20, which obtains an image signal representing the image. In an example, the initial infrared light IR enters the object F and scatters to generate the to-be-sensed infrared light IR1. In anther example, the initial infrared light IR is reflected by the surface (e.g., a ridge of the finger) of the object F to generate the to-be-sensed infrared light IR1. The divergence angles of the light source of the IR source 30 are preferably concentrated to prevent the light from travelling back to the optical sensor 20. The divergence angle of the light source ranges between 0 and 45 degrees, and are usually determined according to the place position of the light source. The divergence angle of the light source, which is more frequently used, ranges between 10 and 20 degrees, for example. The IR source 30 can be implemented by the IR light emitting diode (LED) or laser diode (LD), such as the vertical cavity surface emitting laser (VCSEL) diode. The wavelength of the initial infrared light IR ranges between 800 nanometers (nm) and 1,600 nanometers, are not completely absorbed by the OLED panel, and generally have the transmittance ranging between 30% and 10% for the OLED panel. For example, the wavelength of 850 nm or 940 nm can be used. If the interference of sunlight needs to be avoided, then the wavelengths of 940 nm and 1,350 nm can be used.

A distance D between the optical sensor 20 and the IR source 30 ranges between 3 mm and 12 mm. If the distance D is too long, then it is difficult for the IR light to enter the finger and then be received by the optical sensor 20. If the distance D is too short, then the IR light that has not passed through the display panel 10 can interfere with the sensing result of the optical sensor 20. According to the research test in this disclosure, the distance D relates to the light receiving area of the optical sensor 20 and the dimension of the finger. The implementable distance D ranges between 2 and 10 mm, and the proposed distance D ranges between 6 and 8 mm.

The controller 40 is electrically connected to the display panel 10, the IR source 30 and the optical sensor 20, and controls operations of the display panel 10, the IR source 30 and the optical sensor 20. The controller 40 drives the display panel 10 and the IR source 30 according to different clocks to prevent the interference between the display panel 10 and the IR source 30 and to prevent the display effect from being affected.

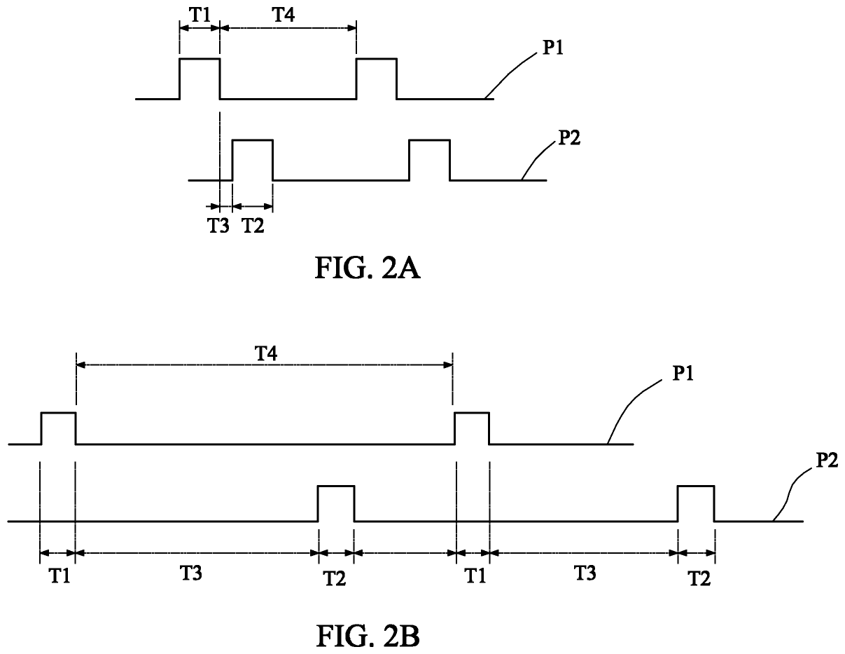

Referring to FIGS. 2A and 2B, the controller 40 disables the IR source 30 in a first period T1 when the display pixels 11 are enabled. In addition, the controller 40 enables the IR source 30 in a second period T2 of a disable period T4 when the display pixels 11 are disabled. The second period T2 lags behind the first period T1 by a third period T3. That is, the display pixels 11 and the IR source 30 are alternately disabled and enabled by the controller 40. The second period T2 may be determined according to the sensitivity of the optical sensor 20. That is, the second period T2 relates to the sensitivity of the optical sensor 20. In one example, the second period T2 ranges between 100 microseconds and 8 milliseconds, or between 500 microseconds and 2 milliseconds. In another example, the second period T2 is substantially equal to 1 millisecond. Although the controller 40 explained in the embodiment is an element built in the display 100, it is worth noting that this disclosure is not limited thereto. In another example, an external controller or another control means can be used to control the above-mentioned operations as long as the IR source 30 can be disabled in the first period T1 when the display pixels 11 are enabled, and can be enabled in the second period T2 of the disable period T4 when the display pixels 11 are disabled.

Compared with the application of visible light, it is easier for the IR light sensing to realize the anti-spoofing identification. If the IR light sensing is not well controlled, then the problem of the bright spot or spot light on the OLED display panel occurs more easily. If the second period T2 is shorter, then the problem of the spot light can be reduced. Using the driving method of the controller 40 can obtain both the biometrics characteristic sensing and displaying functions, and can prevent the IR source from affecting the display effect of the display panel 10.

Optional details will be further explained in the following.

Referring to FIG. 1, the controller 40 can be configured to include a first driver 41 and a second driver 43. The first driver 41 drives the display pixels 11 to display information. The second driver 43 is connected to the first driver 41 through a device driver interface (DDI) 42. The second driver 43 generates a second clock signal P2 according to a first clock signal P1, according to which the first driver 41 drives the display pixels 11, to drive the IR source 30 to generate the initial infrared light IR.

In order to extract an image signal of the fingerprint smoothly, the controller 40 can further include a signal extractor 44, which is electrically connected to the optical sensor 20, and extracts the image signal. The signal extractor 44 judges whether the image signal of the optical sensor 20 needs to be integrated according to the second clock signal P2. If the image signal needs to be integrated, then image signals obtained in multiple first periods T1 need to be summated to increase the signal-to-noise ratio.

In addition, a relative position between the IR source 30 and the display panel 10 may have different changes, and the third period T3 may be adjusted according to the property of the actual display panel in order to eliminate the white flickering. A perpendicular distance between the IR source 30 and the display panel 10 may also be adjusted according to the property of the actual display panel to prevent the infrared light IR from repeatedly reflecting inside the display panel 10 because the repeatedly reflecting infrared light IR causes drawbacks of increased image background and suddenly increased noise. In one example, the third period T3 may be determined according to the relative position between the IR source 30 and the display panel 10. That is, the third period T3 relates to the relative position between the IR source 30 and the display panel 10.

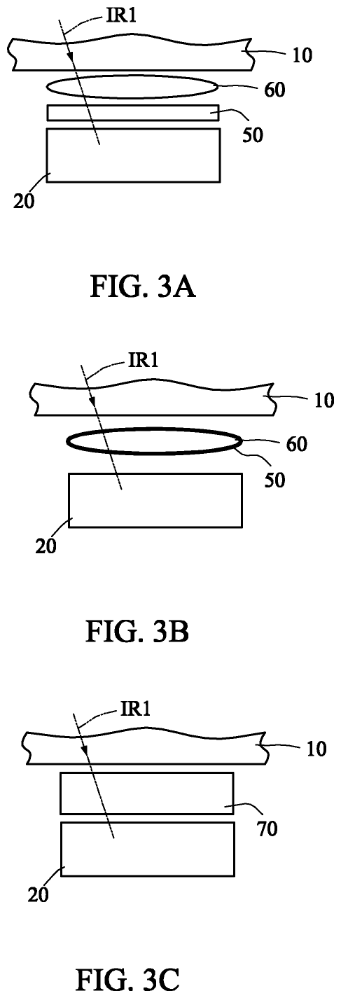

Referring to FIG. 3A, in order to prevent the optical sensor 20 from receiving the visible light band of the display panel 10, the display 100 can further include a band-pass filter layer 50, which is disposed between the display panel 10 and the optical sensor 20, allows the to-be-sensed infrared light IR1 to pass and disallows the visible light VL from passing. In addition, the display 100 may further include a lens module 60, which is disposed between the display panel 10 and the optical sensor 20 (disposed between the band-pass filter layer 50 and the display panel 10 in this example, and may also be disposed between the band-pass filter layer 50 and the optical sensor 20 in another example (not shown)), and focuses the to-be-sensed infrared light IR1 onto the optical sensor 20.

The band-pass filter layer 50 may have other configurations. For example, in FIG. 3B, the band-pass filter layer 50 is coated onto the lens module 60, and the selective filter effect can be achieved similarly. Alternatively, the band-pass filter layer 50 may also be coated onto the light receiving surface of the optical sensor 20.

Alternatively, the optical sensor 20 may be constructed into a collimated optical sensing module. That is, as shown in FIG. 3C, the display 100 may further include a collimator 70, which is disposed between the display panel 10 and the optical sensor 20, and collimates and then transmits the to-be-sensed infrared light IR1 to the optical sensor 20.

In addition, as shown in FIGS. 1, 2A and 2B, this disclosure also provides an optical sensing module 200, which includes the optical sensor 20, the IR source 30 and the second driver 43. When the optical sensing module 200 is electrically connected to a panel drive module 45 (including the first driver 41 and the DDI 42) for driving the display panel 10, the IR source 30 and/or the optical sensor 20 may be driven according to the operation of the first driver 41.

The optical sensor 20 senses the image of the object F through the upper display panel 10. The first driver 41 drives the display pixels 11 of the display panel 10 to display information. The IR source 30 is disposed below the display panel 10, and provides the initial infrared light IR penetrating through the display panel 10 to illuminate the object F. The object F generates the to-be-sensed infrared light IR1 penetrating through the display panel 10 and being received by the optical sensor 20, which obtains an image signal representing the image. The second driver 43 is connected to the first driver 41, and generates the second clock signal P2 according to the first clock signal P1, according to which the first driver 41 drives the display pixels 11, to drive the IR source 30 to generate the initial infrared light IR, so that the second clock signal P2 disables the IR source 30 in the first period T1 when the first clock signal P1 enables the display pixels 11, and that the second clock signal P2 enables the IR source 30 in the second period T2 of the disable period T4 when the first clock signal P1 disables the display pixels 11. That is, the first clock signal P1 and the second clock signal P2 are enabled in different time periods.

Upon implementation of hardware or software control, the optical sensing module 200 needs to obtain the refresh frequency of the display pixel 11 from the DDI 42 of the panel drive module 45, and operates the light-emitting frequency of the LED/LD of the IR source 30 according to the refresh frequency of the display pixel 11 to illuminate the finger. Therefore, the LED/LD needs a special light source driving element (second driver 43), and needs to define the second clock signal P2 according to the first clock signal P1 driven by the display pixel 11.

The optical sensing module 200 may further include the signal extractor 44, and the signal extractor 44 and the second driver 43 may constitute a sensor driving module 46. In addition, referring to FIGS. 3A to 3C, the optical sensing module 200 may further include the band-pass filter layer 50, the lens module 60 and/or the collimator 70, wherein relevant contents may refer to the above-mentioned details, so detailed descriptions thereof will be omitted.

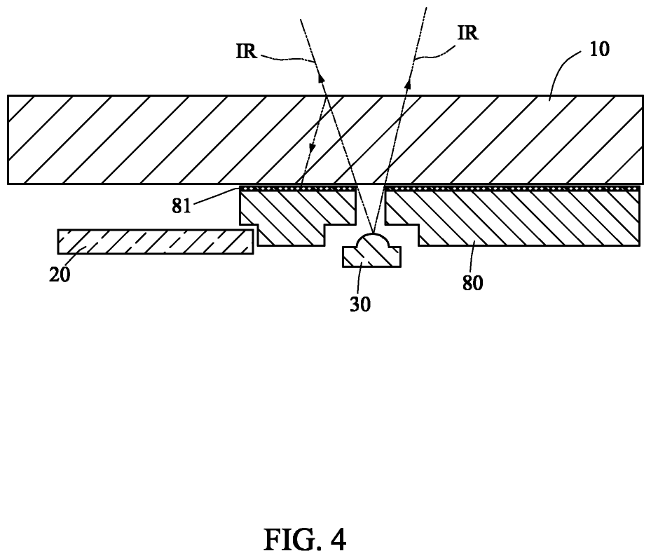

Optionally, as shown in FIG. 4, a light-absorbing material 82 may be disposed or attached between a middle frame 80 of the display 100 and the display panel 10 to prevent the initial infrared light IR, outputted by the IR source 30, from repeatedly reflecting inside the glass of the display panel 10 to cause the stray light interference. Therefore, a bonding surface of the middle frame 80 to the display panel 10, such as the OLED display panel, may be configured as a light-absorbing surface for absorbing the initial infrared light IR reflected by the display panel 10 to reduce the impact of the repeated reflections. Alternatively, if the optical sensor 20 is used in conjunction with the lens-type light-receiving structure, then an anti-reflective film may also be coated onto the lens to decrease the repeated reflections.

With the above-mentioned embodiments, different clocks can be used to respectively drive the optical sensor and the display to prevent a white flickering phenomenon of the display while achieving the optical sensing function. For the display provided with the FOD sensor, the first clock signal for driving the display pixels can be obtained through the DDI of the existing OLED display panel to define the second clock signal for driving the IR source, wherein the second clock signal and the first clock signal have the corresponding delay times to avoid the white flickering phenomenon.

While this disclosure has been described by way of examples and in terms of preferred embodiments, it is to be understood that this disclosure is not limited thereto. To the contrary, it is intended to cover various modifications. Therefore, the scope of the appended claims should be accorded the broadest interpretation so as to encompass all such modifications.

What is claimed is:

1. A display, comprising:
a display panel having display pixels and providing visible light to display information;
an optical sensor being disposed below the display panel and sensing an image of an object disposed above the display panel; and
an infrared (IR) source being disposed below the display panel and providing initial IR light penetrating through the display panel to illuminate the object, which generates to-be-sensed IR light penetrating through the display panel and being received by the optical sensor, which obtains an image signal representing the image, wherein the IR source is disabled in a first period when the display pixels are enabled, and is enabled in a second period of a disable period when the display pixels are disabled, and the second period lags behind the first period by a third period.

2. The display according to claim 1, further comprising a controller, which is electrically connected to the display panel, the IR source and the optical sensor, and controls operations of the display panel, the IR source and the optical sensor, wherein the controller disables the IR source in the first period; and the controller enables the IR source in the second period.

3. The display according to claim 2, wherein the controller comprises:
a first driver driving the display pixels to display information; and
a second driver, which is connected to the first driver through a device driver interface, wherein the second driver generates a second clock signal according to a first clock signal, according to which the first driver drives the display pixels, to drive the IR source to generate the initial IR light.

4. The display according to claim 3, wherein the controller further comprises:
a signal extractor, which is electrically connected to the optical sensor, extracts the image signal, and judges whether the image signal of the optical sensor needs to be integrated according to the second clock signal in order to increase a signal-to-noise ratio.

5. The display according to claim 1, wherein the third period relates to a relative position between the IR source and the display panel.

6. The display according to claim 1, wherein the second period relates to sensitivity of the optical sensor.

7. The display according to claim 1, wherein the second period ranges from 100 microseconds to 8 milliseconds.

8. The display according to claim 1, further comprising a band-pass filter layer, which is disposed between the display panel and the optical sensor, allows the to-be-sensed IR light to pass, and disallows the visible light from passing.

9. The display according to claim 1, further comprising a lens module, which is disposed between the display panel and the optical sensor, and focuses the to-be-sensed IR light onto the optical sensor.

10. The display according to claim 9, further comprising a band-pass filter layer, which is disposed between the lens module and the optical sensor, allows the to-be-sensed IR light to pass, and disallows the visible light from passing.

11. The display according to claim 9, further comprising a band-pass filter layer, which is coated onto the lens module, allows the to-be-sensed IR light to pass and disallows the visible light from passing.

12. The display according to claim 1, wherein a distance between the optical sensor and the IR source ranges from 3 mm to 12 mm.

13. The display according to claim 1, further comprising a collimator, which is disposed between the display panel and the optical sensor, and collimates and then transmits the to-be-sensed IR light to the optical sensor.

14. The display according to claim 1, further comprising a light-absorbing material, which is disposed between a middle frame above the IR source and the display panel, and absorbs the initial IR light reflected back by the display panel.

15. An optical sensing module, comprising:
an optical sensor sensing an image of an object through a display panel placed above the optical sensor, wherein a first driver drives display pixels of the display panel to display information;
an infrared (IR) source being disposed below the display panel and providing initial IR light penetrating through the display panel to illuminate the object, which generates to-be-sensed IR light penetrating through the display panel and being received by the optical sensor, which obtains an image signal representing the image; and
a second driver to be connected to the first driver, wherein the second driver generates a second clock signal according to a first clock signal, according to which the first driver drives the display pixels, to drive the IR source to generate the initial IR light, so that the second clock signal disables the IR source in a first period when the first clock signal enables the display pixels; and that the second clock signal enables the IR source in a second period of a disable period when the first clock signal disables the display pixels, wherein the second period lags behind the first period by a third period.

16. The optical sensing module according to claim 15, further comprising a signal extractor, which is electrically connected to the optical sensor, extracts the image signal, wherein the signal extractor judges whether the image signal of the optical sensor needs to be integrated according to the second clock signal in order to increase a signal-to-noise ratio.

17. The optical sensing module according to claim 15, wherein the third period relates to a relative position between the IR source and the display panel.

18. The optical sensing module according to claim 15, wherein the second period relates to sensitivity of the optical sensor.

19. The optical sensing module according to claim 15, wherein the second period ranges from 100 microseconds to 8 milliseconds.

20. The optical sensing module according to claim 15, further comprising a band-pass filter layer, which is disposed between the display panel and the optical sensor, allows the to-be-sensed IR light to pass, and disallows visible light, outputted from the display pixels, from passing.

21. The optical sensing module according to claim 15, further comprising a lens module, which is disposed between the display panel and the optical sensor, and focuses the to-be-sensed IR light onto the optical sensor.

22. The optical sensing module according to claim 21, further comprising a band-pass filter layer, which is disposed between the lens module and the optical sensor, allows the to-be-sensed IR light to pass, and disallows visible light, outputted from the display pixels, from passing.

23. The optical sensing module according to claim 21, further comprising a band-pass filter layer, which is coated onto the lens module, allows the to-be-sensed IR light to pass, and disallows visible light, outputted from the display pixels, from passing.

24. The optical sensing module according to claim 15, wherein a distance between the optical sensor and the IR source ranges from 3 mm to 12 mm.

25. The optical sensing module according to claim 15, further comprising a collimator, which is disposed between the display panel and the optical sensor, and collimates and then transmits the to-be-sensed IR light to the optical sensor.
